(19) United States
(12) Patent Application Publication
(10) Pub. No.: US 2024/0290850 A1
(43) Pub. Date: Aug. 29, 2024

(54) SEMICONDUCTOR STRUCTURE WITH BACKSIDE SELF-ALIGNED CONTACT AND METHOD FOR FORMING SAME

(71) Applicant: Taiwan Semiconductor Manufacturing Company, Ltd., Hsin-Chu (TW)

(72) Inventors: Yun Ju Fan, Hsinchu City (TW); Chun-Yuan Chen, Hsinchu (TW); Huan-Chieh Su, Changhua County (TW); Chih-Hao Wang, Hsinchu County (TW)

(21) Appl. No.: 18/348,851

(22) Filed: Jul. 7, 2023

Related U.S. Application Data
(60) Provisional application No. 63/487,223, filed on Feb. 27, 2023.

(51) Int. Cl. H01L 29/417; H01L 21/8234; H01L 23/48; H01L 27/088; H01L 29/06; H01L 29/423; H01L 29/66; H01L 29/775; H01L 29/78; H01L 29/786

(52) U.S. Cl. CPC H01L 29/41733; H01L 21/823412; H01L 21/823418; H01L 21/823431; H01L 21/823475; H01L 21/823481; H01L 23/481; H01L 27/0886; H01L 29/0673; H01L 29/41791; H01L 29/42392; H01L 29/66439; H01L 29/66545; H01L 29/66795; H01L 29/775; H01L 29/7851; H01L 29/78696

(57) ABSTRACT

A method includes forming a fin over a semiconductor layer, depositing an isolation feature on sidewalls of the fin, recessing a portion of the fin to form a first trench exposing a top surface of the semiconductor layer, forming a sacrificial feature in the first trench, forming an epitaxial feature over the sacrificial feature, exposing a bottom surface of the sacrificial feature, removing the sacrificial feature to form a second trench exposing a bottom surface of the epitaxial feature, and forming a conductive feature in the second trench. The conductive feature electrically couples to the epitaxial feature.

### PRIORITY DATA

This application claims priority to U.S. Provisional Patent Application No. 63/487,223 filed on Feb. 27, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

ICs have progressed to advanced technologies with smaller feature sizes, such as 7 nm, 5 nm and 3 nm. In these advanced technologies, the gate pitch (spacing) continuously shrinks and therefore induces contact to gate bridge concern. Furthermore, multi-gate transistors, such as those formed on fin-type active regions, are often desired for enhanced device performance. Those three-dimensional field effect transistors (FETs) formed on fin-type active regions are also referred to as FinFETs. Other three-dimensional field-effect transistors include gate-all-around (GAA) FETs. Those FETs are required narrow fin width for short channel control, which leads to smaller source/drain regions than those of planar FETs. This will reduce the alignment margins and cause issues for further shrinking device pitches and increasing packing density. Along with the scaling down of the device sizes, power lines are formed on the backside of the substrate. However, the existing backside power rails still face various challenges including shorting, leakage, routing resistance, alignment margins, layout flexibility, and packing density. Therefore, there is a need for a structure and method for multi-gate transistors with backside power rails and vias to address these concerns for enhanced circuit performance and reliability.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1A and 1B illustrate a flowchart of an example method for making a semiconductor device in accordance with some embodiments of the present disclosure.

FIGS. 2A, 3A, 4A, 5A, 6A, 7A, 8A, 9A, 10A, 11A, 12A, 13A, 14A, 15A, 16A, 17A, 18A, 19A, 20A, 21A, 22A, 23A, 24A, and 25A illustrate perspective views of a semiconductor device constructed according to the method in FIGS. 1A and 1B, in accordance with some embodiments.

FIGS. 2B, 3B, 4B, 5B, 6B, 7B, 8B, 9B, 10B, 11B, 12B, 13B, 14B, 15B, 16B, 17B, 18B, 19B, 20B, 21B, 22B, 23B, 24B, and 25B illustrate cross-sectional views in a Y-Z plane of a portion of the semiconductor device in respective perspective views during fabrication processes according to the method of FIGS. 1A and 1B, in accordance with some embodiments of the present disclosure.

FIGS. 2C, 3C, 4C, 5C, 6C, 7C, 8C, 9C, 10C, 11C, 12C, 13C, 14C, 15C, 16C, 17C, 18C, 19C, 20C, 21C, 22C, 23C, 24C, and 25C illustrate cross-sectional views in an X-Z plane of a portion of the semiconductor device in respective perspective views during fabrication processes according to the method of FIGS. 1A and 1B, in accordance with some embodiments of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure provides a semiconductor structure with backside power rails and the method of making the same. The semiconductor structure further includes a backside via (also referred to as a backside contact) feature disposed on the backside of the substrate and interposed between the semiconductor active regions (such as fin active regions) and the backside power rail, and electrically connecting the backside power rail to a device feature (such as a source feature of a field-effect transistor (FET)) on the semiconductor active regions. Especially, the backside via feature is self-aligned with the device feature (such as a source feature) to be electrically connected, thus providing the connection without overlay shifting and eliminating the shorting issue, such as shorting between the corresponding metal gate electrode and the backside power rail, which is connected to a source/drain feature though a via feature.

The semiconductor structure also includes an interconnect structure formed on the frontside of the substrate. The interconnect structure further includes a front contact feature electrically connected to the FETs, such as landing on and connecting to a drain feature of a transistor, thus distributing power rails to frontside and backside of the substrate, reducing the number of power lines from the frontside and providing more space for metal routing and processing margin on the frontside of the substrate. Such formed semiconductor structure includes backside power rails on the backside and the interconnect structure on the frontside to collectively route power lines, such as the drain features being connected to the corresponding power lines through the interconnect structure and source features being connected to the corresponding power lines through the backside power rails. In some embodiments, both frontside and backside contact features include silicide to reduce contact resistance. The disclosed structure and the method of making the same are applicable to a semiconductor structure having FETs with a three-dimensional structure, such as fin FETs (FinFETs) formed on fin active regions, and FETs with vertically-stacked multiple channels, such as gate-all-around (GAA) structure. For the purposes of simplicity. the present disclosure uses GAA transistors as an example. Those of ordinary skill in the art should appreciate that they may readily use the present disclosure as a basis for designing or modifying other processes and structures (such as FinFETs and/or planar FETs) for carrying out the same purposes and/or achieving the same advantages of the embodiments introduced herein.

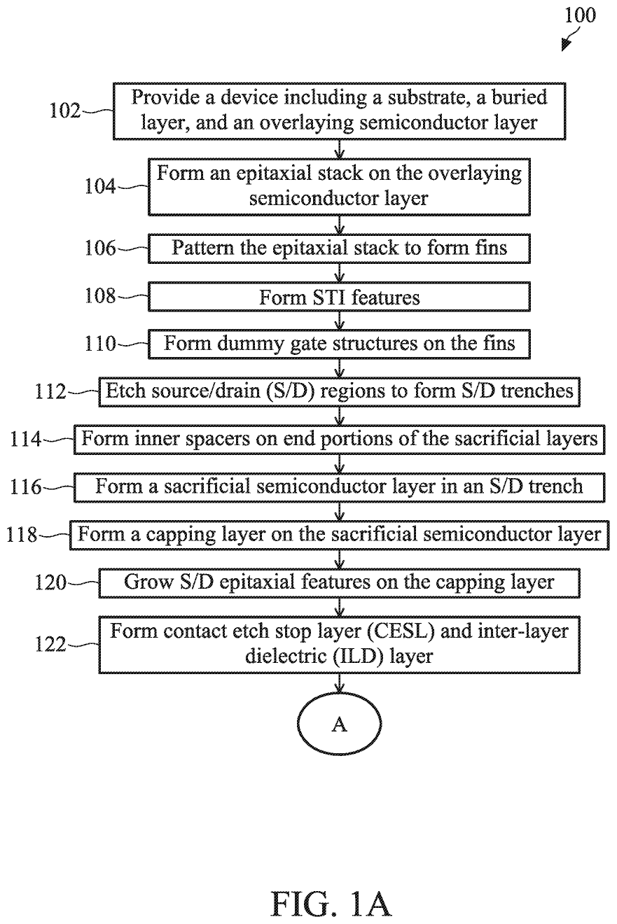

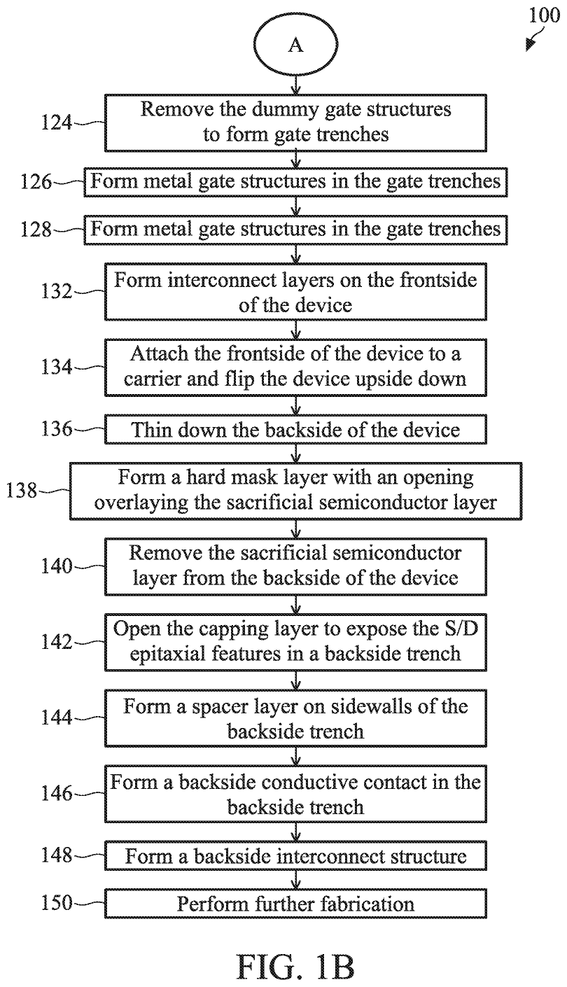

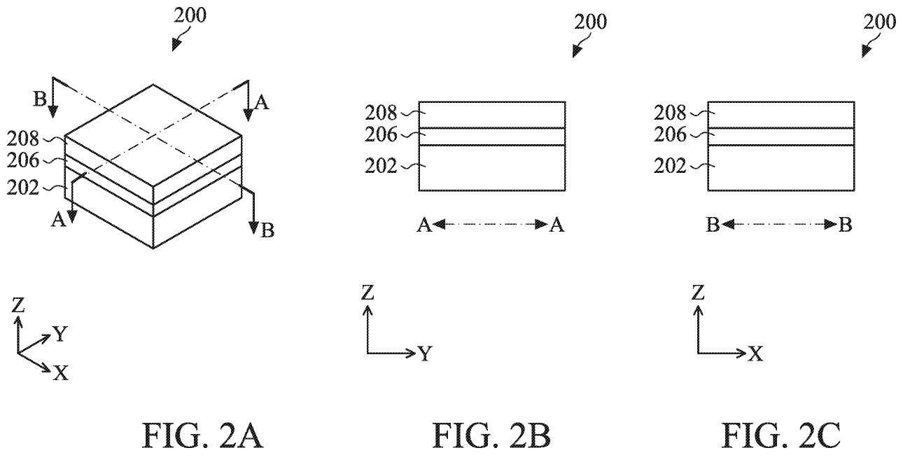

FIGS. 1A and 1B illustrate a flow chart of a method 100 for fabricating a semiconductor device according to various embodiments of the present disclosure. Additional processing is contemplated by the present disclosure. Additional operations can be provided before, during, and after method 100, and some of the operations described can be moved, replaced, or eliminated for additional embodiments of method 100. FIGS. 1A and 1B are described below in conjunction with FIG. 2A through FIG. 25C that illustrate various perspective and cross-sectional views of a semiconductor device (or device) 200 at various steps of fabrication according to the method 100, in accordance with some embodiments. In some embodiments, the device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof. FIGS. 2A through 25C have been simplified for the sake of clarity to better understand the inventive concepts of the present disclosure. Additional features can be added in the device 200, and some of the features described below can be replaced, modified, or eliminated in other embodiments of the device 200.

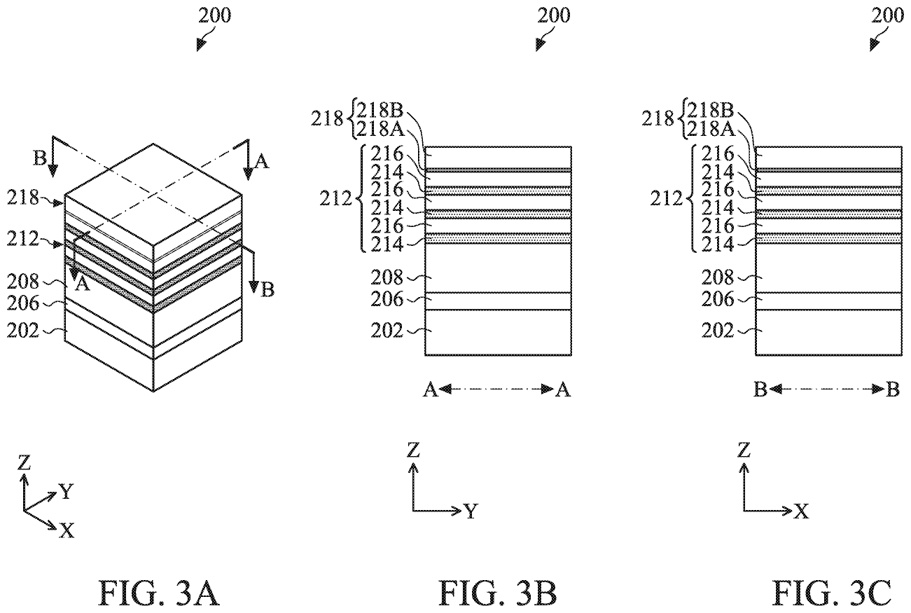

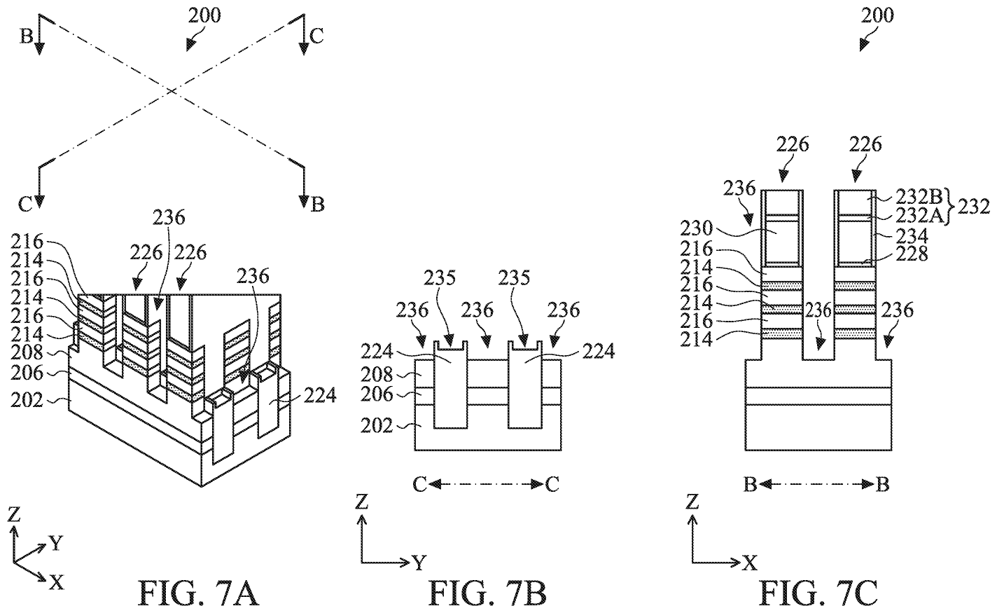

At operation 102, the method 100 (FIG. 1A) provides a device 200 having a substrate 202, a buried layer 206 disposed on the substrate 202, and a semiconductor layer 208 disposed on the buried layer 206, as shown in FIGS. 2A-2C. FIG. 2A illustrates a perspective view of the device 200, and FIGS. 2B and 2C illustrate cross-sectional views of the device 200, in portion, along the A-A line and the B-B line in FIG. 2A, respectively. Particularly, the A-A line is a cut along the lengthwise direction of to-be-formed gate structures (direction “Y” or Y-direction) and the B-B line is a cut along the lengthwise direction of to-be-formed semiconductor fins (direction “X” or X-direction). The A-A lines and B-B lines in FIGS. 3A through 25C are similarly configured. Some of the figures (such as FIG. 7B) in FIGS. 3A through 25C also illustrate cross-sectional views of the device 200, in portion, along a C-C line, which is parallel to the A-A line and cut in a source/drain (S/D) region of the device 200.

In some embodiments, the substrate 202 is a silicon-on-insulator (SOI) substrate. Semiconductor-on-insulator substrates can be fabricated using separation by implantation of oxygen (SIMOX), wafer bonding, and/or other suitable methods. In an alternative embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. The device 200 also includes a buried layer 206 disposed on the substrate 202. The buried layer 206 may be an oxide layer, such as silicon oxide, or a semiconductor layer, such as GaAs. The device 200 further includes a semiconductor layer 208 disposed on the buried layer 206. In some embodiments, the substrate 202 and the semiconductor layer 208 may both include bulk single-crystalline silicon, and the buried layer 206 includes GaAs. A concentration of Ga (molar ratio) in the buried layer 206 may range from about 20% to about 55%. Alternatively, the buried layer 206 may be a buried oxide layer. Further, ins some embodiments, the substrate 202 and the semiconductor layer 208 may include different semiconductor compositions, such as but not limited to Si, Ge, SiGe, GaAs, InSb, GaP, GaSb, InAlAs, InGaAs, GaSbP, GaAsSb, InP, or combinations thereof. Still further, in some alternative embodiments, the formation of the buried layer 206 may be optionally skipped, such that the semiconductor layer 208 may be disposed on the top surface of the substrate 202.

At operation 104, the method 100 (FIG. 1A) forms an epitaxial stack 212 over the semiconductor layer 208, as shown in FIGS. 3A-3C. The epitaxial stack 212 includes epitaxial layers 214 of a first composition interposed by epitaxial layers 216 of a second composition. The first and second compositions can be different. In an embodiment, the epitaxial layers 214 are SiGe layers and the epitaxial layers 216 are Si layers. However, other embodiments are possible including those that provide for a first composition and a second composition having different oxidation rates and/or etch selectivity. As described further below, the epitaxial layers 216 or portions thereof form channel regions of the device 200. In the depicted embodiment, the epitaxial stack 212 includes three epitaxial layers 214 and three epitaxial layers 216 configured to form three semiconductor layer pairs disposed over the substrate 202, each semiconductor layer pair having a respective first epitaxial layer 214 and a respective second epitaxial layer 216. After undergoing subsequent processing, such configuration will result in the device 200 having three channel layers. However, the present disclosure contemplates embodiments where the epitaxial stack 212 includes more or less semiconductor layers, for example, depending on a number of channels desired for the device 200 (e.g., a GAA transistor) and/or design requirements of the device 200. For example, the epitaxial stack 212 can include two to ten epitaxial layers 214 and two to ten epitaxial layers 216. In an alternative embodiment where the device 200 is a FinFET device, the epitaxial stack 212 is simply one layer of a semiconductor material, such as one layer of Si. As will be discussed, the method 100 will process layers at both sides of the substrate 202. In the present disclosure, the side of the substrate 202 where the epitaxial stack 212 resides is referred to as the frontside and the side opposite the frontside is referred to as the backside.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the epitaxial layers 216, include the same material as the overlaying semiconductor layer 208, such as Si. In some embodiments, either of the epitaxial layers 214 and 216 may include a different material than the overlaying semiconductor layer 208. In furtherance of the embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation and etch selectivity properties. In some embodiments, the epitaxial layers 214 have a first etch rate to an etchant and the epitaxial layers 216 have a second etch rate to the etchant, where the second etch rate is less than the first etch rate. In some embodiments, the epitaxial layers 214 have a first oxidation rate and the epitaxial layers 216 have a second oxidation rate, where the second oxidation rate is less than the first oxidation rate. In the depicted embodiment, the epitaxial layers 214 and the epitaxial layers 216 include different materials, constituent atomic percentages, constituent weight percentages, thicknesses, and/or characteristics to achieve desired etching selectivity during an etching process, such as an etching process implemented to form suspended channel layers in channel regions of the device 200. For example, where the epitaxial layers 214 include silicon germanium and the epitaxial layers 216 include silicon, a silicon etch rate of the epitaxial layers 216 is less than a silicon germanium etch rate of the epitaxial layers 214 for given etchant. In some embodiments, the epitaxial layers 214 and the epitaxial layers 216 can include the same material but with different constituent atomic percentages to achieve the etching selectivity and/or different oxidation rates. For example, the epitaxial layers 214 and the epitaxial layers 216 can include silicon germanium, where the epitaxial layers 214 have a first silicon atomic percent and/or a first germanium atomic percent and the epitaxial layers 216 have a second, different silicon atomic percent and/or a second, different germanium atomic percent. The present disclosure contemplates that the epitaxial layers 214 and the epitaxial layers 216 include any combination of semiconductor materials that can provide desired etching selectivity, desired oxidation rate differences, and/or desired performance characteristics (e.g., materials that maximize current flow), including any of the semiconductor materials disclosed herein.

In some embodiments, the epitaxial layer 214 has a thickness ranging from about 3 nm to about 6 nm. In furtherance of the embodiments, the epitaxial layers 214 in the epitaxial stack 212 may be substantially uniform in thickness. In yet some alternative embodiments, the bottommost epitaxial layer 214 may be thicker than other upper epitaxial layers 214, such as about 20% to about 50% thicker. In some embodiments, the epitaxial layer 216 has a thickness ranging from about 4 nm to about 12 nm. In furtherance of the embodiments, the epitaxial layers 216 in the epitaxial stack 212 are substantially uniform in thickness. As described in more detail below, in the illustrated embodiment, the epitaxial layers 216 serve as channel layers for a GAA transistor and the thickness is chosen based on device performance considerations. The epitaxial layers 214 serve to reserve a spacing (or referred to as a gap) between adjacent channel structures for a GAA transistor and the thickness is chosen based on device performance considerations as well. Accordingly, the epitaxial layers 214 are also referred to the sacrificial layers 214, and the epitaxial layers 216 are also referred to as the channel layers 216 or the nanostructures 216.

Further, at the operation 104, a mask layer 218 is formed over the epitaxial stack 212. In some embodiments, the mask layer 218 includes a first mask layer 218A and a second mask layer 218B. The first mask layer 218A is a pad oxide layer made of silicon oxide, which can be formed by a thermal oxidation process. The second mask layer 218B is made of silicon nitride (SiN), which is formed by chemical vapor deposition (CVD), including low pressure CVD (LPCVD) and plasma enhanced CVD (PECVD), physical vapor deposition (PVD), atomic layer deposition (ALD), or other suitable process.

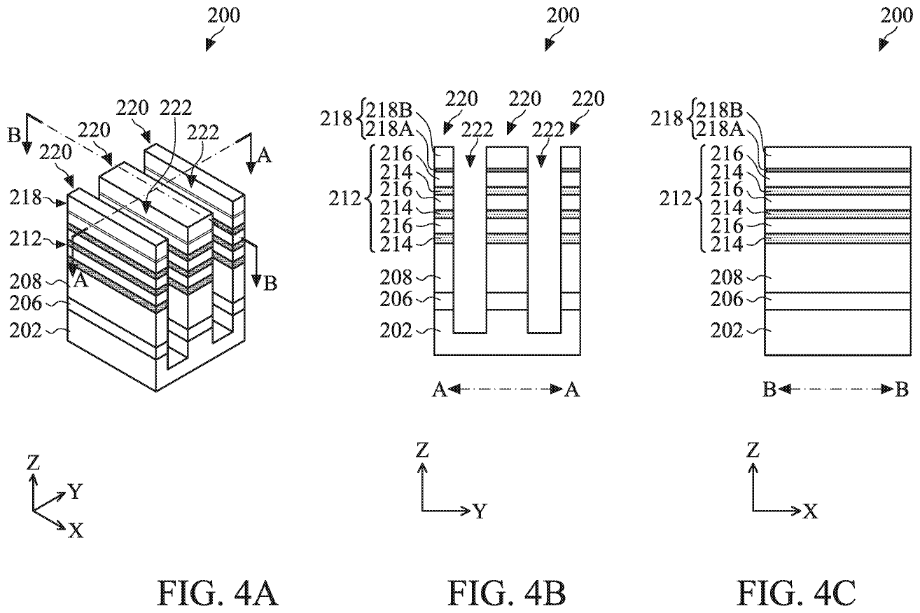

At operation 106, the method 100 (FIG. 1A) patterns the epitaxial stack 212 to form semiconductor fins 220 (also referred to as fins 220), as shown in FIGS. 4A-4C. In various embodiments, each of the fins 220 includes a top portion of the interleaved epitaxial layers 214 and 216 and a bottom portion that is formed by patterning the semiconductor layer 208, the buried layer 206, and a top portion of the substrate 202. The bottom portion of a fin 220 is also referred to as a fin base or a mesa. That is, in the illustrated embodiment, the fin base or mesa includes the semiconductor layer 208, the buried layer 206, and a top portion of the substrate 202. The mask layer 218 is patterned into a mask pattern by using patterning operations including photo-lithography and etching. In some embodiments, the operation 106 patterns the epitaxial stack 212 using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the epitaxial stack 212 in an etching process, such as a dry etch (e.g., reactive ion etching), a wet etch, and/or other suitable process, through openings defined in the patterned mask layer 218. Trenches 222 are defined between opposing sidewalls of the adjacent fins 220. In the depicted embodiment, the trenches 222 extend through the buried layer 206 and expose a recessed top surface of the substrate 202. The

Still referring to FIGS. 4A-4C, each of the fins 220 protrudes upwardly in the Z-direction above the substrate 202 and extends lengthwise in the X-direction. In FIGS. 4A-4C, three (3) fins 220 are spaced apart along the Y-direction. But the number of the fins is not limited to three, and may be as small as one, two, or more than three. The fins 220 may have a uniform fin width along the Y-direction. Notably, in FIG. 4B, the portion of the device 200 with two fin pitches spanning in the Y-direction is shown for simplicity of illustration, and thus the left-most and the right-most fins 220 each have only a half fin width shown in FIG. 4B. In some embodiments, one or more dielectric fins (not shown) are formed on both sides of each of the fins 220 to improve fin density and fin structural fidelity.

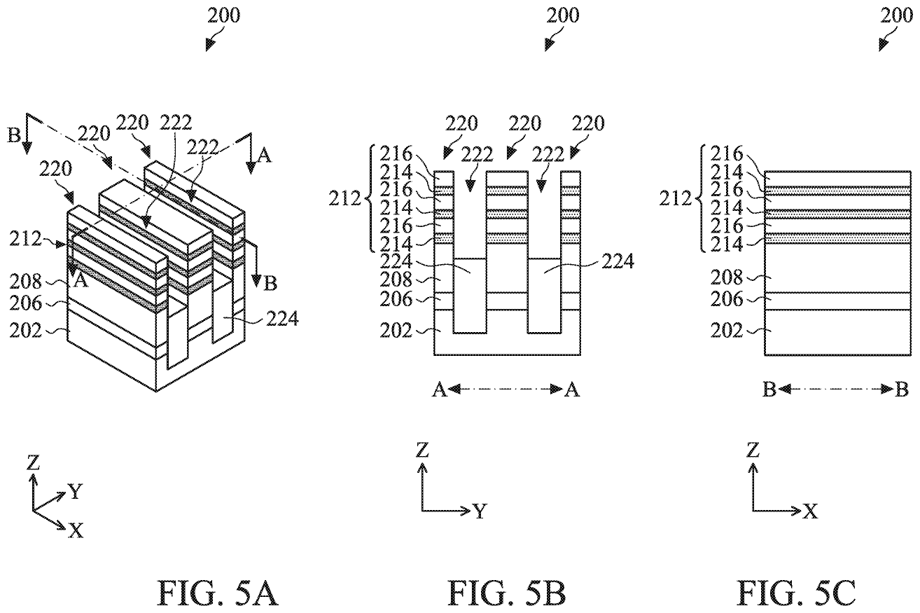

At operation 108, the method 100 (FIG. 1A) deposits a dielectric material in the trenches 222 between adjacent fins 220 to form an isolation feature 224, as shown in FIGS. 5A-5C. The isolation feature 224 may include one or more dielectric layers. Suitable dielectric materials for the isolation feature 224 may include silicon oxides, silicon nitrides, silicon carbides, fluorosilicate glass (FSG), low-K dielectric materials, and/or other suitable dielectric materials. The dielectric material may be deposited by any suitable technique including thermal growth, CVD, HDP-CVD, PVD, ALD, and/or spin-on techniques. Then, a planarization operation, such as a CMP process, is performed such that the upper surface of the topmost epitaxial layer 216 is exposed from the isolation feature 224. The isolation features 224 is subsequently recessed to form shallow trench isolation (STI) features (thus also denoted as STI features 224). Any suitable etching technique may be used to recess the isolation features 224 including dry etching, wet etching, RIE, and/or other etching methods, and in an exemplary embodiment, an anisotropic dry etching is used to selectively remove the dielectric material of the isolation features 224 without etching the fins 220. In some embodiments, the mask layer 218 is removed by a CMP process performed prior to the recessing of the isolation features 224. In some embodiments, the mask layer 218 is removed by an etchant used to recess the isolation features 224. In the illustrated embodiment as shown in FIG. 5B, the top surface of the STI features 224 may be below the bottom surface of the epitaxial stack 212 (also the top surface of the semiconductor layer 208) and above the top surface of the buried layer 206. Alternatively, the top surface of the STI features 224 may be coplanar with the bottom surface of the epitaxial stack 212, in accordance with some other embodiments.

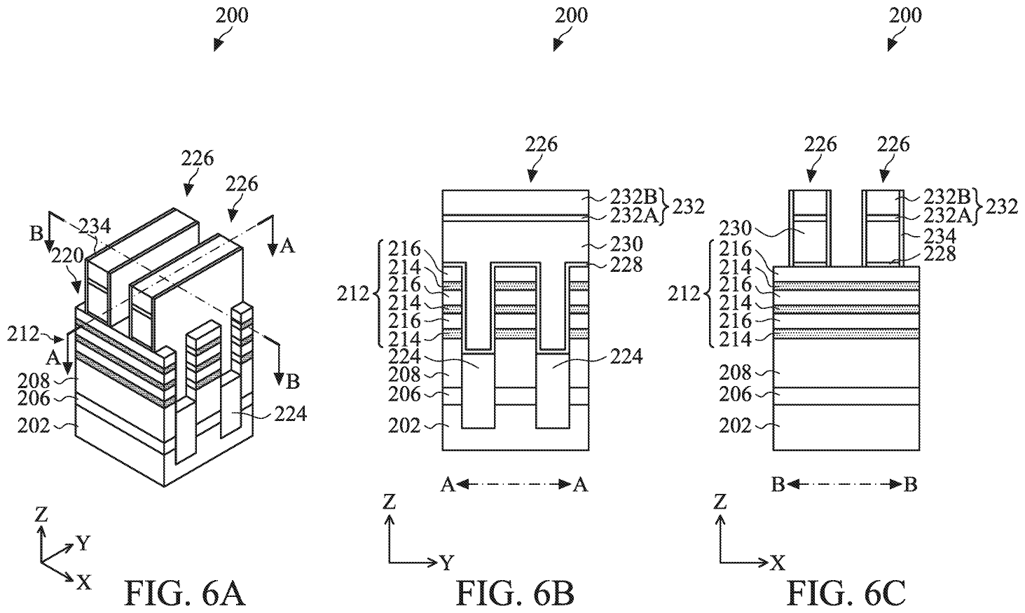

At operation 110, the method 100 (FIG. 1A) forms sacrificial (dummy) gate structures 226, as shown in FIGS. 6A-6C. In the illustrated embodiment, two (2) sacrificial gate structures 226 are formed, but the number of the sacrificial gate structures 226 is not limited to one, two, or more sacrificial gate structures, which are arranged in the X-direction. The sacrificial gate structures 226 are formed over portions of the fins 220 which are to be channel regions. The sacrificial gate structures 226 define channel regions of the to-be-formed GAA transistors. Each sacrificial gate structure 226 includes a sacrificial gate dielectric layer 228 and a sacrificial gate electrode layer 230. The sacrificial gate structure 226 is formed by first blanket depositing the sacrificial gate dielectric layer 228 over the fins 220. A sacrificial gate electrode layer 230 is then deposited on the sacrificial gate dielectric layer 228 and over the fins 220. The sacrificial gate electrode layer 230 includes silicon such as polycrystalline silicon or amorphous silicon. In some embodiments, the sacrificial gate electrode layer 230 is subjected to a planarization operation. The sacrificial gate dielectric layer 228 and the sacrificial gate electrode layer 230 may be deposited using CVD, including LPCVD and PECVD, PVD, ALD, or other suitable process. Subsequently, a mask layer 232 is formed over the sacrificial gate electrode layer 230. The mask layer 232 may include a pad silicon oxide layer 232A and a silicon nitride mask layer 232B. Subsequently, a patterning operation is performed on the mask layer 232 and sacrificial gate dielectric and electrode layers are patterned into the sacrificial gate structures 226. By patterning the sacrificial gate structures 226, the fins 220 are partially exposed on opposite sides of the sacrificial gate structures 226, thereby defining source/drain (S/D) regions.

Still referring to FIGS. 6A-6C, the method 100 (FIG. 1A) at operation 110 also forms gate spacers 234 on sidewalls of the sacrificial gate structures 226. The gate spacers 234 may include a dielectric material such as silicon oxide, silicon nitride, silicon carbide, silicon oxynitride, SiCN films, silicon oxycarbide, SiOCN films, and/or combinations thereof. In some embodiments, the gate spacers 234 include multiple layers, such as main spacer walls, liner layers, and the like. By way of example, the gate spacers 234 may be formed by blanket depositing a dielectric material layer in a conformal manner over the sacrificial gate structures 226 using processes such as, a CVD process, a subatmospheric CVD (SACVD) process, a flowable CVD process, an ALD process, a PVD process, or other suitable process. In the illustrated embodiment, the deposition of the dielectric material layer is followed by an etching-back (e.g., anisotropically) process to remove the dielectric material layer from horizontal surfaces and expose the top surface of the sacrificial gate structures 226 and the top surface of the fins 220 adjacent to but not covered by the sacrificial gate structures 226 (e.g., S/D regions). The dielectric material layer may remain on the sidewalls of the sacrificial gate structures 226 as the gate spacers 234 (and/or on the sidewalls of the fins 220 as the fin spacers). The etching-back process may also recess a top portion of the STI feature 224 in forming a recess 235 (as seen in FIG. 7B) due to the limited etching contrast between the dielectric materials of the gate spacers 234 and the STI features 224. In some embodiments, the etching-back process may include a wet etch process, a dry etch process, a multiple-step etch process, and/or a combination thereof.

At operation 112, the method 100 (FIG. 1A) recesses portions of the fins 220 to form S/D trenches (or S/D recesses) 236 in the S/D regions, as shown in FIGS. 7A-7C. The stacked epitaxial layers 214 and 216 are etched down at the S/D regions. In many embodiments, operation 112 forms the S/D trenches 236 by a suitable etching process, such as a dry etching process, a wet etching process, or an RIE process. The etching process at operation 112 may implement a dry etching process using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof. The etchant is selected such that a top portion of the semiconductor layer 208 is recessed, and sidewalls of the STI features 224 are exposed in the S/D trenches 236. In the illustrated embodiment as shown in FIG. 7B, the S/D trenches 236 may extend to a position below a bottom surface of the recess 235 formed in the top portion of the STI features 224.

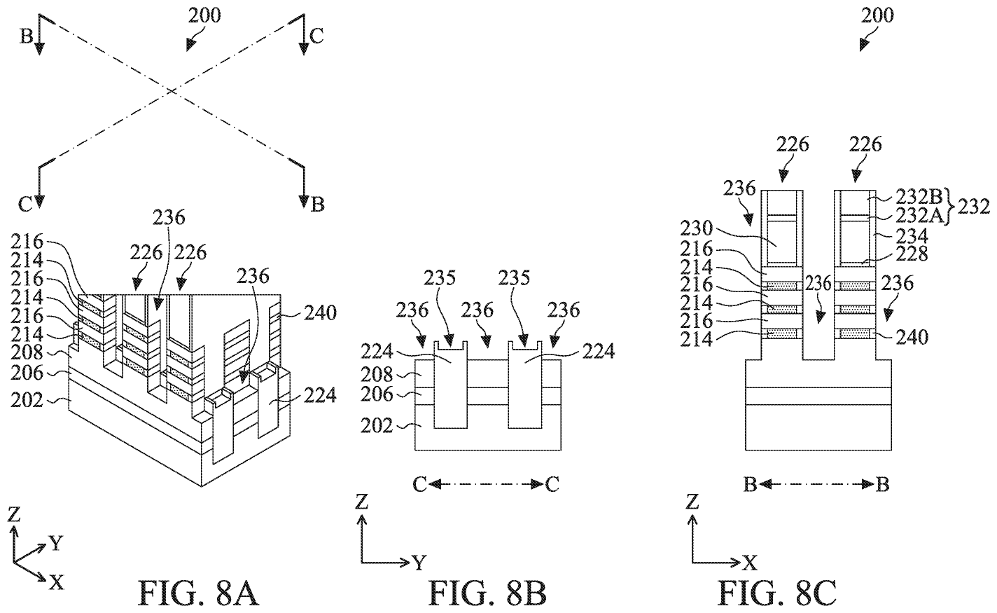

At operation 114, the method 100 (FIG. 1A) forms inner spacers 240 abutting end portions of the epitaxial layers 214, as shown in FIGS. 8A-8C. Operation 114 may first laterally etch the end portions of the epitaxial layers 214, thereby forming cavities to be filled by a dielectric material as the inner spacers 240. The epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, operation 114 may first selectively oxidize lateral ends of the epitaxial layers 214 that are exposed in the S/D trenches 236 to increase the etch selectivity between the epitaxial layers 214 and 216. In some examples, the oxidation process may be performed by exposing the device 200 to a wet oxidation process, a dry oxidation process, or a combination thereof. Next, operation 114 forms inner spacers 240 on the recessed lateral ends of the upper epitaxial layers 214. By way of example, operation 114 may include blanket depositing an inner spacer material layer in the S/D trenches 236. Particularly, the inner spacer material layer is deposited on the recessed lateral ends of the upper epitaxial layers 214 exposed in the cavities and on the sidewalls of the epitaxial layers 216 exposed in the S/D trenches 236. The inner spacer material layer may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer with substantially uniform thickness on different surfaces. The inner spacer material layer can be formed by ALD or any other suitable method. By conformally forming the inner spacer material layer, a volume of the cavities is reduced or completely filled. After the inner spacer material layer is deposited, an etching operation is performed to partially remove the inner spacer material layer from the S/D trenches 236. Particularly, the inner spacer material layer is removed from the sidewalls of the epitaxial layers 216. By this etching, the inner spacer material layer remains substantially within the cavities, because of a small volume of the cavities. Generally, plasma dry etching etches a layer in wide and flat areas faster than a layer in concave (e.g., holes, grooves and/or slits) portions. Thus, the inner spacer material layer can remain inside the cavities. The remaining portions of the inner spacer material layer inside the cavities provides isolation between to-be-formed metal gate structures and to-be-formed S/D epitaxial features, which are referred to as the inner spacers 240.

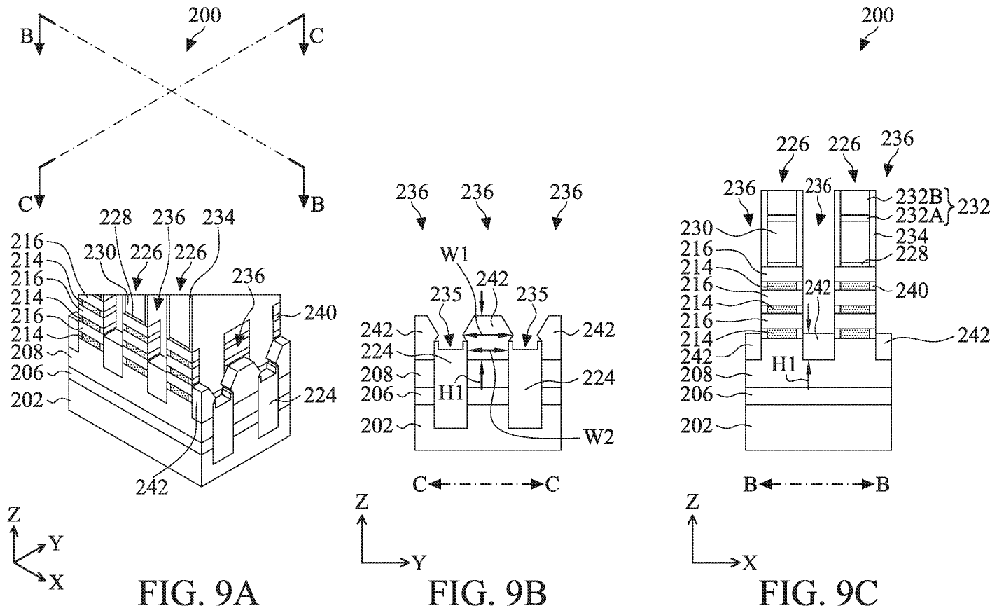

At operation 116, the method 100 (FIG. 1A) forms a semiconductor layer 242 in the S/D trenches 236, as shown in FIGS. 9A-9C. The semiconductor layer 242 may be deposited using an epitaxial growth process or by other suitable processes. In some embodiments, epitaxial growth of semiconductor layers 242 is achieved by a molecular beam epitaxy (MBE) process, a chemical vapor deposition (CVD) process, a metalorganic chemical vapor deposition (MOCVD) process, other suitable epitaxial growth process, or combinations thereof. The semiconductor layer 242 includes a semiconductor material that is different than the semiconductor material included in the semiconductor layer 208 to achieve etching selectivity during subsequent processing. For example, semiconductor layers 242 and 208 may include different materials, different constituent atomic percentages, different constituent weight percentages, and/or other characteristics to achieve desired etching selectivity during an etching process. In an embodiment, the semiconductor layer 242 includes silicon germanium, such as undoped silicon germanium, and the semiconductor layer 208 includes silicon. The present disclosure contemplates that semiconductor layers 242 and 208 include any combination of semiconductor materials that can provide desired etching selectivity, including any of the semiconductor materials disclosed herein. As to be discussed in further detail below, the semiconductor layers 242 formed in some of the source regions will be removed in a backside process to form backside vias. Notably, at operation 116, the semiconductor layers 242 may be formed in both the drain regions and source regions, while the semiconductor layers 242 not to be removed in the backside process will remain in the final device, including in the drain regions.

The semiconductor layer 242 is deposited to a thickness such that it is extending up to the bottommost inner spacer 240 (FIG. 9C) and is above the top surface of the STI features 224 (FIG. 9B). In the illustrated embodiment as shown in FIG. 9C, the top surface of the semiconductor layer 242 is above the bottom surface of the bottommost inner spacer 240 and below the top surface of the bottommost inner spacer 240. In some other embodiments, the top surface of the semiconductor layer 242 is substantially level with the bottom surface of the bottommost inner spacers. In various embodiments, the top surface of the semiconductor layer 242 is below the top surface of the bottommost inner spacer 240 to avoid physical contact between the epitaxial layer 216 and the semiconductor layer 242. Otherwise, the backside via that replaces the semiconductor layer 242 in subsequent processes may electrically short to the epitaxial layer 216. In some embodiments, a thickness H1 of the semiconductor layer 242 ranges from about 5 nm to about 20 nm. In the illustrated embodiment as shown in FIG. 9B, a top portion of the semiconductor layer 242 has a width W1 that is larger than a width W2 of the bottom portion of the semiconductor layer 242. In some embodiments, the width W2 ranges from about 5 nm to about 30 nm, and the width W1 ranges from about 25 nm to about 50 nm. The top portion of the semiconductor layer 242 may have crystalline facets due to the epitaxial growth, and edges of the crystalline facets may laterally extend to a position directly above the STI feature 224.

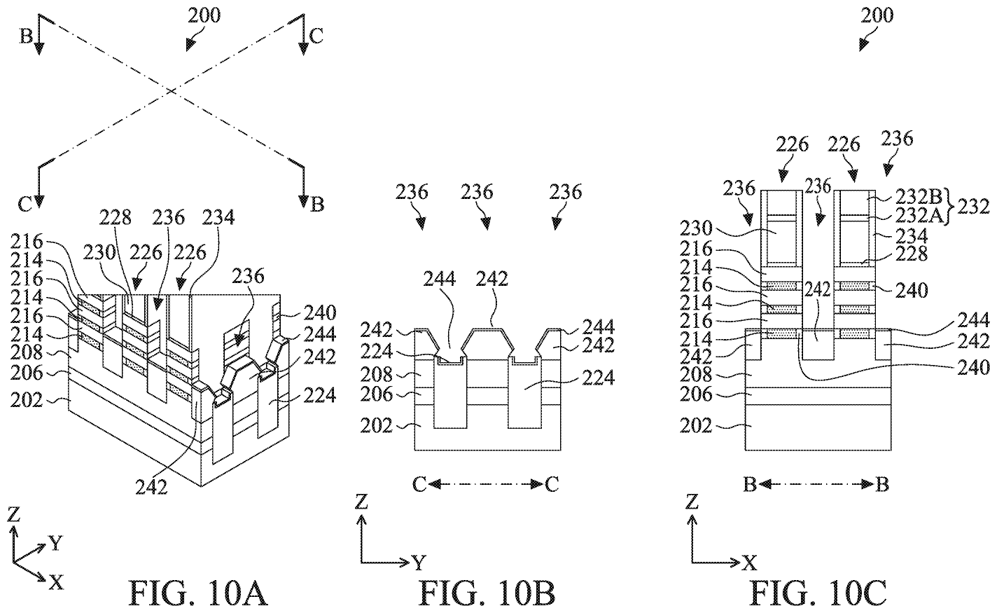

At operation 118, the method 100 (FIG. 1A) forms a capping layer 244 covering at least the top surface of the semiconductor layer 242, as shown in FIGS. 10A-10C. The capping layer 244 may include silicon oxide (SiO₂), aluminum oxide (AlO), silicon nitride (SiN), silicon oxynitride (SiON), silicon carbonitride (SiCN), or silicon carbon oxynitride (SiCON). The capping layer 244 may include the same or different dielectric material compositions with the inner spacers 240, in accordance with some embodiments. Generally, the compositions of the capping layer 244 and the semiconductor layer 242 are selected such that there is a high etch selectivity therebetween. As to be discussed in further details below, the capping layer 244 is used as an etch stop layer during an etch process in protecting an S/D epitaxial feature formed in the S/D trenches 236 during removing the semiconductor layer 242 later. Therefore, if the capping layer 244 fully covers the bottom surface of the S/D epitaxial feature to-be-formed thereon, the capping layer 244 may be sufficient to protect the S/D epitaxial feature and does not have to fully cover the semiconductor layer 242. For example, edge portions of the semiconductor layer 242 (e.g., edges of the crystalline facets) may laterally extend out and not covered by the capping layer 244. In the illustrated embodiment as shown in FIG. 10C, the top surface of the capping layer 244 is substantially level with the bottom surface of the bottommost epitaxial layer 216. Alternatively, the top surface of the capping layer 244 may be above or below the bottom surface of the bottommost epitaxial layer 216. In various embodiments, the top surface of the capping layer 244 is below the top surface of the bottommost epitaxial layer 216. In some embodiments, the capping layer 244 is first deposited in the S/D trenches 236 using CVD, PVD, ALD, or other suitable process, covering the top surface of the semiconductor layer 242 and over the sidewalls of the S/D trenches 236. Subsequently, an etching-back process is performed to remove portions of the capping layer 244 from the sidewalls of the S/D trenches 236, while other portions of the capping layer 244 covering the top surface of the semiconductor layer 242 remain. Any suitable etching technique may be used to partially remove the capping layer 244 from the S/D trenches 236 including dry etching, wet etching, RIE, and/or other etching methods, and in an exemplary embodiment, an anisotropic dry etching is used.

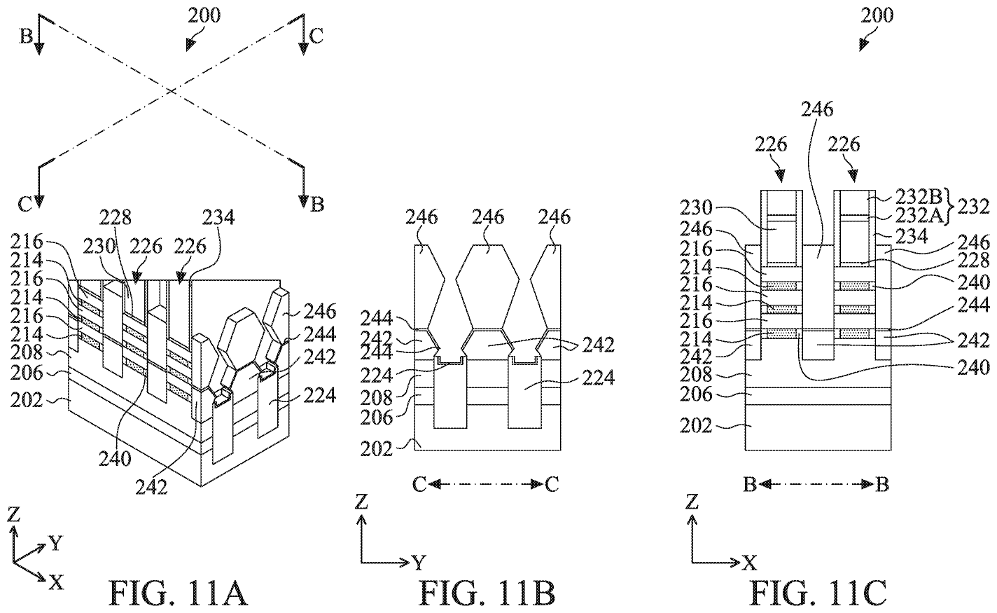

At operation 120, the method 100 (FIG. 1A) forms S/D epitaxial features 246 in the S/D trenches 236, as shown in FIGS. 11A-11C. In some embodiments, the S/D epitaxial features 246 include epitaxially grown semiconductor materials such as epitaxially grown silicon, germanium, or silicon germanium. The S/D epitaxial features 246 can be formed by any epitaxy processes including chemical vapor deposition (CVD) techniques (for example, vapor phase epitaxy and/or Ultra-High Vacuum CVD), molecular beam epitaxy, other suitable epitaxial growth processes, or combinations thereof. The S/D epitaxial features 246 may be doped with n-type dopants and/or p-type dopants. In some embodiments, for n-type transistors, the S/D epitaxial features 246 include silicon and can be doped with carbon, phosphorous, arsenic, other n-type dopant, or combinations thereof (for example, forming Si:C S/D epitaxial features, Si:P S/D epitaxial features, or Si:C:P S/D epitaxial features). In some embodiments, for p-type transistors, the S/D epitaxial features 246 include silicon germanium or germanium, and can be doped with boron, other p-type dopant, or combinations thereof (for example, forming Si:Ge:B S/D epitaxial features). The S/D epitaxial features 246 may include multiple epitaxial semiconductor layers having different levels of dopant density. In some embodiments, annealing processes (e.g., rapid thermal annealing (RTA) and/or laser annealing) are performed to activate dopants in the S/D epitaxial features 246. The bottom surface of the S/D epitaxial features 246 fully rests on the top surface of the capping layer 244.

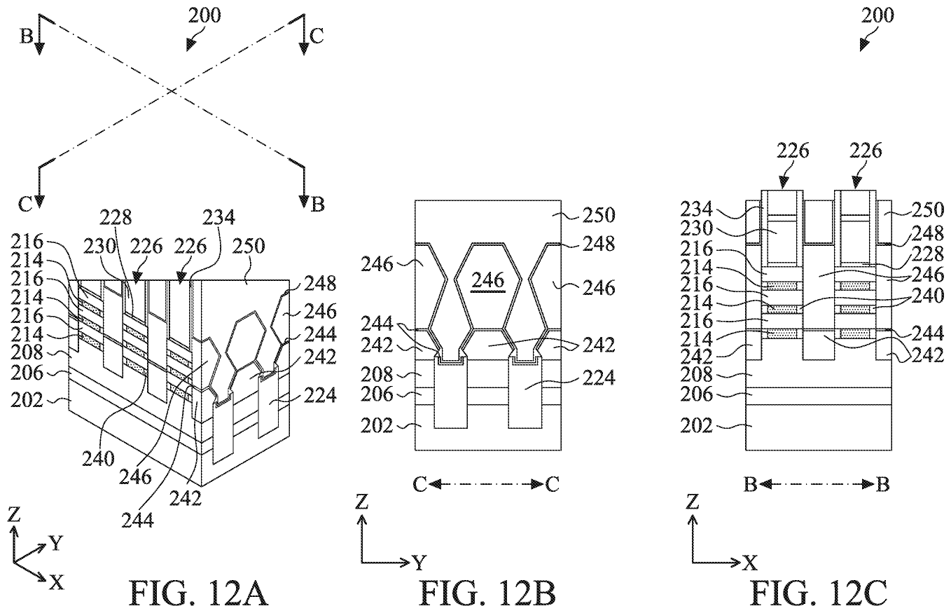

At operation 122, the method 100 (FIG. 1A) forms a contact etch stop layer (CESL) 248 over the S/D epitaxial features 246 and an interlayer dielectric (ILD) layer 250 over the CESL layer 248, as shown in FIGS. 12A-12C. The CESL layer 248 may include silicon nitride, silicon oxynitride, silicon nitride with oxygen (O) or carbon (C) elements, and/or other materials; and may be formed by CVD, PVD (physical vapor deposition), ALD, or other suitable methods. The ILD layer 250 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be formed by PECVD or FCVD (flowable CVD), or other suitable methods. In some embodiments, forming the ILD layer 250 further includes performing a CMP process to planarize a top surface of the device 200, such that the mask layer 232 over top portions of the sacrificial gate structures 226 are removed. The capping layer 244 may separate the semiconductor layer 242 from contacting the CESL 248 and the ILD layer 250. As discussed above, the edge portions of the semiconductor layer 242 may extend beyond the capping layer 244 in some embodiments, and the edge portions of the semiconductor layer 242 may be in contact with the CESL 248 or the ILD layer 250 (if CESL 248 not presented).

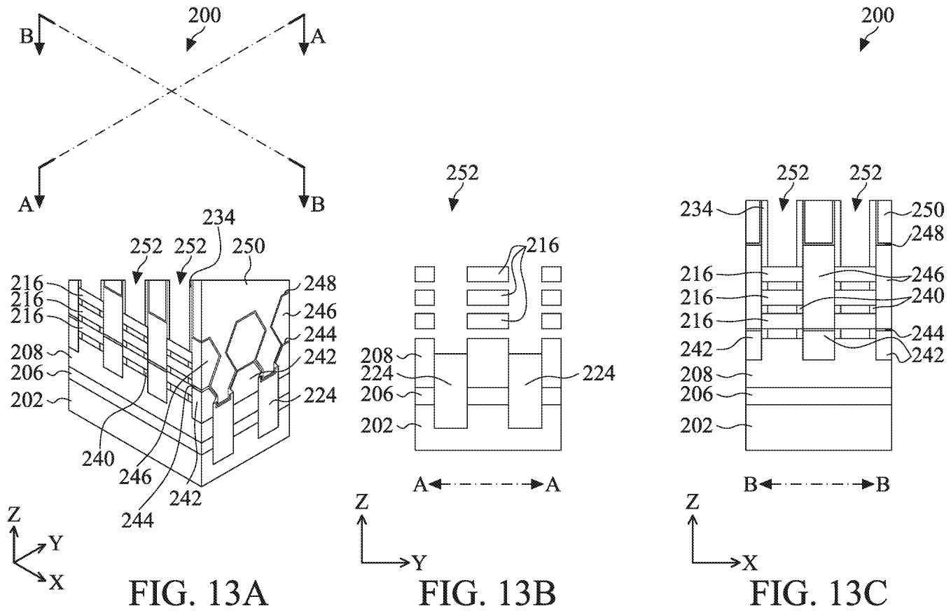

At operation 124, the method 100 (FIG. 1B) removes the sacrificial gate structures 226 to form gate trenches 252 in an etch process, such as plasma dry etching and/or wet etching. The gate trenches 252 expose the epitaxial layers 214 and 216 in channel regions. The operation 124 then releases channel structures from channel regions. The resultant structure at the conclusion of operation 124 is shown in FIGS. 13A-13C. In the illustrated embodiment, channel layers are the epitaxial layers 216 in the form of nanostructures (e.g., nanosheets or nanowires). In the present embodiment, the epitaxial layers 216 include silicon, and the epitaxial layers 214 include silicon germanium. The epitaxial layers 214 are selectively removed. In some implementations, the selectively removal process includes oxidizing the epitaxial layers 214 using a suitable oxidizer, such as ozone. Thereafter, the oxidized epitaxial layers 214 may be selectively removed from the gate trenches 252. To further this embodiment, operation 124 includes a dry etching process to selectively remove the epitaxial layers 214, for example, by applying an HCl gas at a temperature of about 500° C. to about 700° C., or applying a gas mixture of CF₄, SF₆, and CHF₃. For the sake of simplicity and clarity, after the channel structure release, the epitaxial layers 216 are denoted as the channel layers 216.

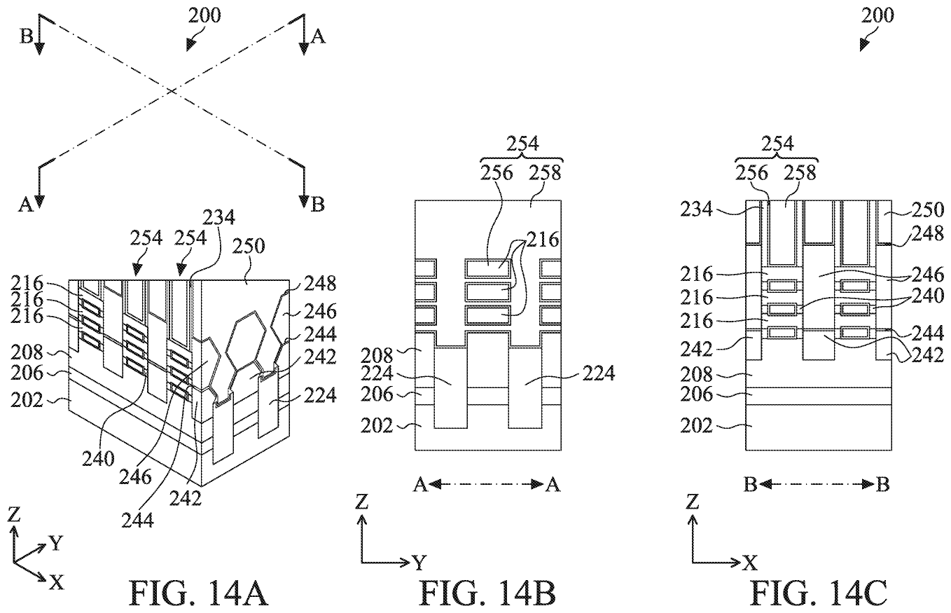

At operation 126, the method 100 (FIG. 1B) forms metal gate structures 254 in the gate trenches 252, as shown in FIGS. 14A-14C. The metal gate structures 254 wrap around each of the channel layers 216 in the channel regions. The inner spacers 240 separate the metal gate structures 254 from contacting the S/D epitaxial features 246. The bottommost inner spacer 240 also separates the metal gate structures 254 from contacting the semiconductor layer 242 and the capping layer 244.

The metal gate structures 254 include a gate dielectric layer 256 wrapping each channel structures 216 in the channel regions and a gate electrode layer 258 formed on the gate dielectric layer 256. In some embodiments, the gate dielectric layer 256 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSION, HfTaO, HfTIO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 256 includes an interfacial layer formed between the channel structures and the high-k dielectric material. The gate dielectric layer 256 may be formed by CVD, ALD or any suitable method. In one embodiment, the gate dielectric layer 256 is formed using a highly conformal deposition process such as ALD in order to ensure the formation of a gate dielectric layer having a uniform thickness around each channel layers. The gate electrode layer 258 is formed on the gate dielectric layer 256 to surround each channel structure 216. The gate electrode layer 258 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 258 may be formed by CVD, ALD, electro-plating, or other suitable method. In certain embodiments of the present disclosure, one or more work function adjustment layers are interposed between the gate dielectric layer and the gate electrode layer. The work function adjustment layers are made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TIN, TiC, Co, TiAl, HfTi, TiSi and TaSi is used as the work function adjustment layer, and for the p-channel FET, one or more of TiAlC, Al, TiAl, TaN, TaAlC, TiN, TiC and Co is used as the work function adjustment layer. The work function adjustment layer may be formed by ALD, PVD, CVD, e-beam evaporation, or other suitable process. Further, the work function adjustment layer may be formed separately for the n-type transistors and the p-type transistors which may use different metal layers.

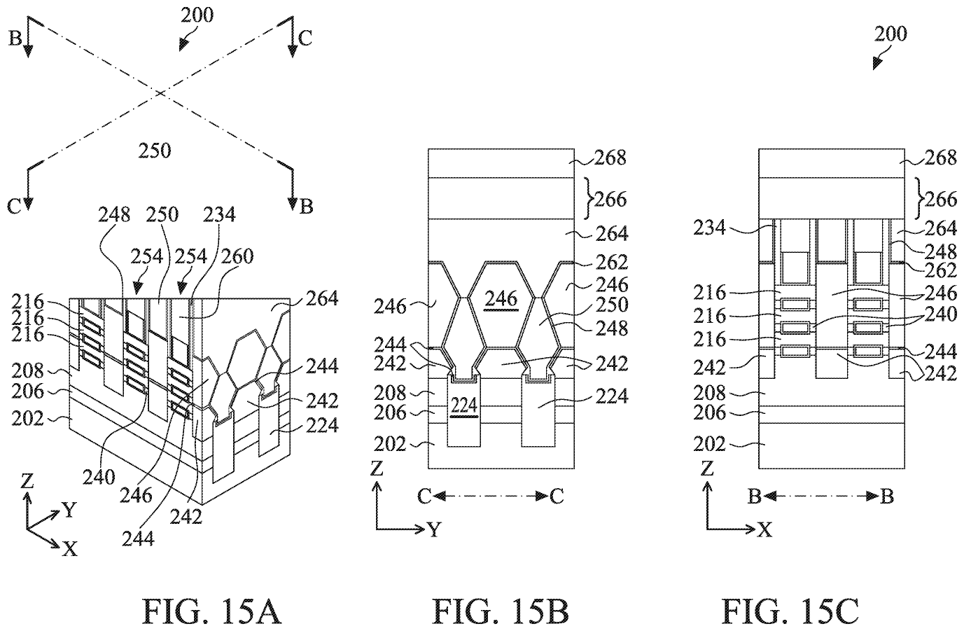

The operation 126 may further include an etching-back process to recess the metal gate structures 254. The metal gate structures 254 are recessed below the upper surface of the gate spacers 234 by a dry and/or a wet etching operation. After the metal gate structures 254 are recessed, a gate cap insulating layer 260 is formed over the recessed metal gate structures 254 (as shown in FIG. 15C). The gate cap insulating layer 260 may include a dielectric material selected from one or more of SiC, SiON, SiOCN, SiCN and SiN. A planarization operation, such as a CMP process, is performed to remove excessive dielectric material of the gate cap insulating layer 260.

At operation 128, the method 100 (FIG. 1B) forms frontside S/D contact features 264 landing on some of the S/D features 246, as shown in FIGS. 15A-15C. The operation 128 may include lithography process and etch to form S/D contact hole(s) to a subset of S/D features. The operation 128 includes one or more etching processes that are tuned selective to the materials of the ILD layer 250, thereby forming contact holes. Further, the operation 128 may further includes an additional etch, such as wet etch, to open the CESL 248 such that those S/D features 246 are exposed within the contact holes. The S/D features 246 may be partially etched in some embodiments. The etching processes can be dry etching, wet etching, reactive ion etching, or other etching methods.

The operation 128 may further include forming silicide features 262 over the S/D features 246 and forming S/D contacts (or vias) features 264 over the silicide features 262. Since the silicide features 262 and the S/D contacts 264 are formed at the frontside of the device 200, they are also referred to as frontside silicide features 262 and frontside S/D contacts 264, respectively.

The process of forming the silicide features 262 in the operation 128 includes depositing one or more metals into the contact holes, performing an annealing process to the device 200 to cause reaction between the one or more metals and the S/D features 246 to produce the silicide features 262, and removing un-reacted portions of the one or more metals, leaving the silicide features 262 in the contact holes. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The silicide features 262 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

The S/D contacts 264 may include a conductive barrier layer and a metal fill layer over the conductive barrier layer. The conductive barrier layer functions to prevent metal materials of the metal fill layer from diffusing into the dielectric layers adjacent the S/D contact features 354. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), or other metals, and may be formed by CVD, PVD, ALD, plating, or other suitable processes. In some embodiments, the conductive barrier layer is omitted in the S/D contacts 264. The operation 128 may perform a CMP process to remove excessive materials of the S/D contacts 264.

At operation 132, the method 100 (FIG. 1B) forms one or more interconnect layers 266 with contacts, vias, and wires embedded in dielectric layers, as shown in FIGS. 15A-15C. The one or more interconnect layers 266 connect gate, source, and drain electrodes of various transistors, as well as other circuits in the device 200, to form an integrated circuit in part or in whole. In some embodiments, the operation 132 includes performing one or more middle-end-of-line (MEOL) and back-end-of-line (BEOL) processes. This may include forming gate contact vias and source/drain contact vias, intermetal dielectric (IMD) layers, metal lines embedded in IMD layers, contact pads, etc. The device 200 may further include passivation layers and/or other layers built on the frontside of the device 200. These layers and the one or more interconnect layers are collectively denoted with the numeral 266.

At operation 134, the method 100 (FIG. 1B) attaches the frontside of the device 200 to a carrier 268, as shown in FIGS. 15A-15C. The carrier 268 may be a silicon wafer in some embodiments. The operation 134 may use any suitable attaching processes, such as direct bonding. hybrid bonding, using adhesive, or other bonding methods. In the illustrated embodiment, an adhesive layer (not shown) is formed on the frontside of the device 200 and adjoins the carrier 268 to the frontside of the device 200. The operation 134 may further include alignment, annealing. and/or other processes. The attaching of the carrier 268 allows the device 200 to be flipped upside down. This makes the device 200 accessible from the backside of the device 200 for further processing. It is noted that the device 200 is flipped upside down starting in the following figures.

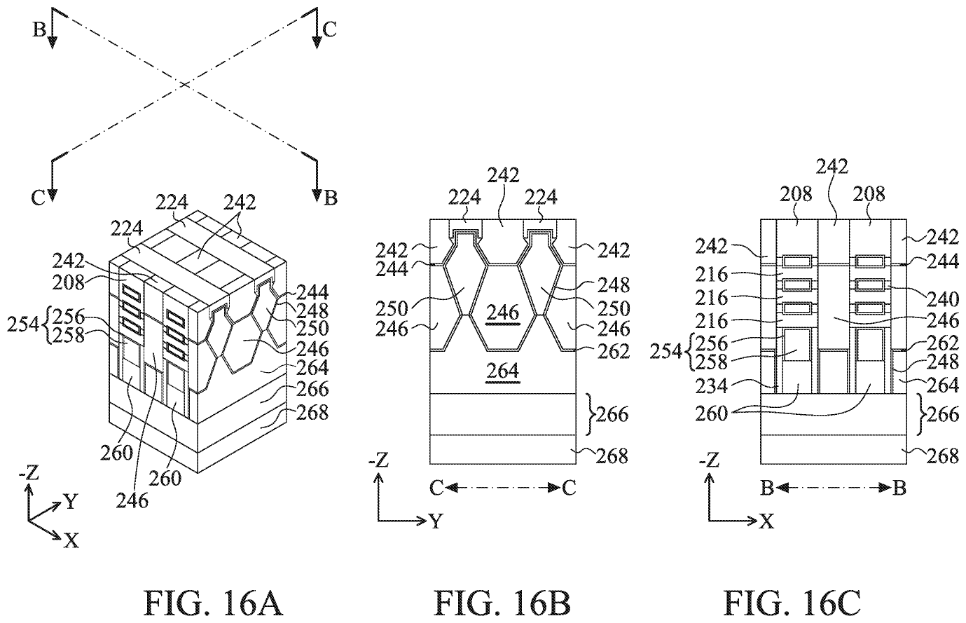

At operation 136, the method 100 (FIG. 1B) flips the device 200 upside down to make the device 200 accessible from the backside of the device 200 for further processing, as shown in FIGS. 16A-16C. Starting from FIGS. 16A-16C, the “Z” direction points from the backside of the device 200 to the frontside of the device 200, while the “−z” direction points from the frontside of the device 200 to the backside of the device 200.

Still referring to FIGS. 16A-16C, the operation 136 also thins down the device 200 from the backside of the device 200 until the semiconductor layer 242 is exposed from the backside of the device 200. The thinning process may include a mechanical grinding process and/or a chemical thinning process. The substrate 202 may be first removed in a chemical thinning process with the buried layer 206 as an etch stop layer. Afterwards, a mechanical grinding process may be applied to fully remove the buried layer 206 and substantial amount of the semiconductor layer 208 and the STI features 224 with the semiconductor layer 242 as a planarization stop layer.

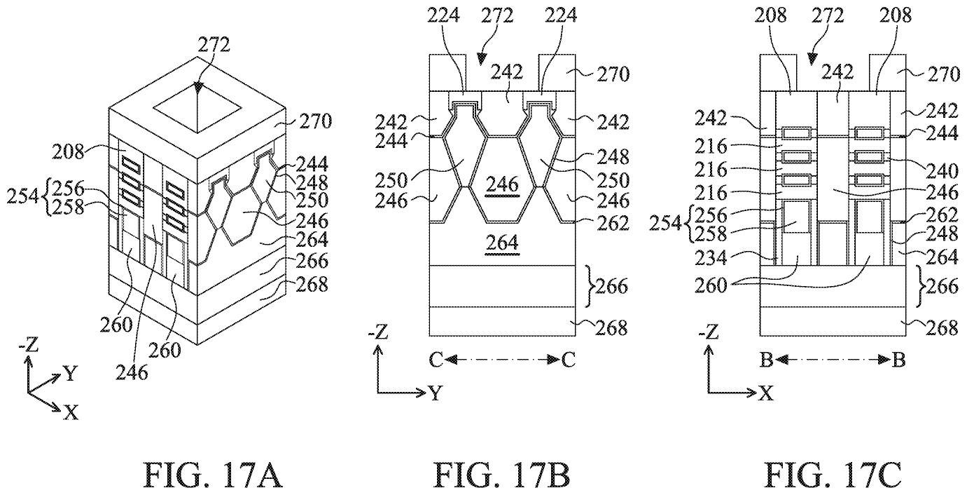

At operation 138, the method 100 (FIG. 1B) forms a hard mask layer 270 on the backside of the device 200, as shown in FIGS. 17A-17C. The hard mask layer 270 may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable materials. A thickness of the hard mask layer 270 may range from about 5 nm to about 30 nm. A lithography patterning and etching process is performed to pattern the hard mask layers 270. Particularly, the lithography process forms a patterned photoresist layer with an opening, and an etching process is applied to transfer the opening to the hard mask layers 270 as the opening 272. The opening 272 is larger than the bottom surface of the semiconductor layer 242, such that the bottom surface of the semiconductor layer 242 is fully exposed in the opening 272. A portion of the STI features 224 is also exposed in the opening 272 (FIG. 17B), and a portion of the semiconductor layer 208 is also exposed in the opening 272 (FIG. 17C).

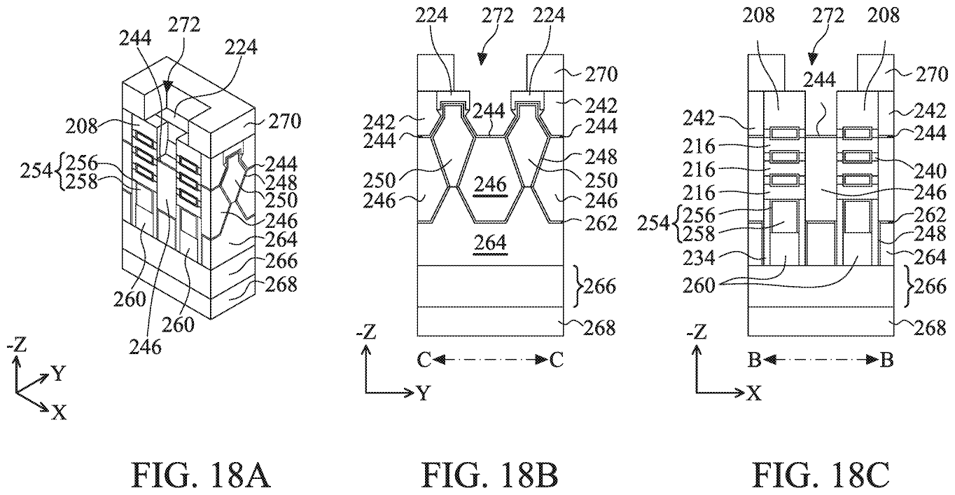

At operation 140, the method 100 (FIG. 1B) selectively etches the semiconductor layer 242 to extend the opening 272 to the capping layer 244, as shown in FIG. 18A-18C. The opening 272 is also referred to as the backside trench 272. The backside trench 272 exposes the surfaces of the semiconductor layer 208, the capping layer 244, and the STI features 224. In some embodiments, the operation 140 applies an etching process that is tuned to be selective to the materials (e.g., SiGe) in the semiconductor layer 242 and with no (or minimal) etching to the semiconductor layer 208, the STI feature 224, and the capping layer 244. The bottommost inner spacer 240 may also be exposed in the backside trench 272 (FIG. 18C).

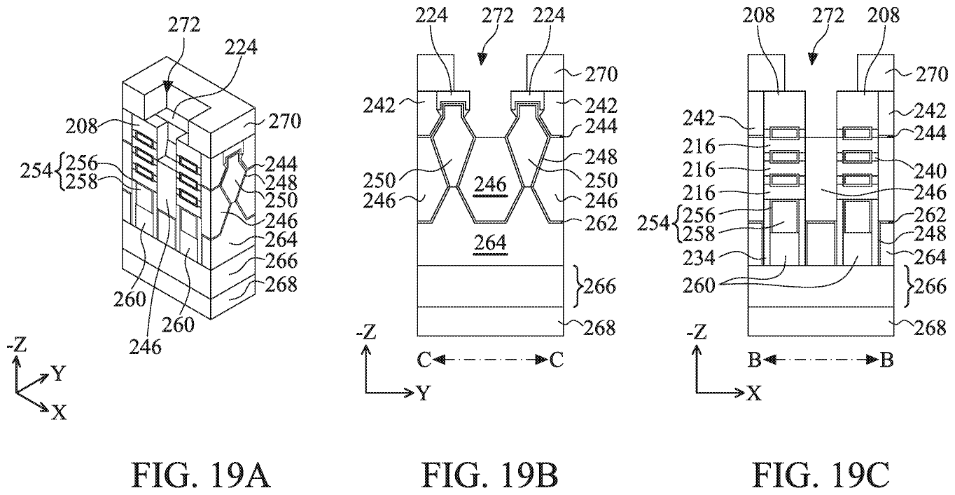

At operation 142, the method 100 (FIG. 1B) performs an additional etch to open the capping layer 244, thereby exposing the bottom surface of the S/D features 246, as shown in FIGS. 19A-19C. In the illustrated embodiment, the CESL 248 is also exposed in the backside trench 272 (FIG. 19B). In some alternative embodiment, the formation of the capping layer 244 at operation 118 is optionally skipped, and the S/D feature 246 is directly formed on the semiconductor layer 242. Thus, the S/D feature 246 is already exposed in the backside trench 272 at the conclusion of the operation 140 by selectively etching the semiconductor layer 242, and the operation 142 may be skipped. In the illustrated embodiment, the bottom surface of the one S/D feature 246 that is exposed in the backside trench 272 and the bottom surfaces of the adjacent S/D features 246 that are still covered are substantially level. In an alternative embodiment, the etching process also etches the S/D epitaxial features 246 to recess the exposed surface to a level that is below the bottom surfaces of the adjacent S/D features 246.

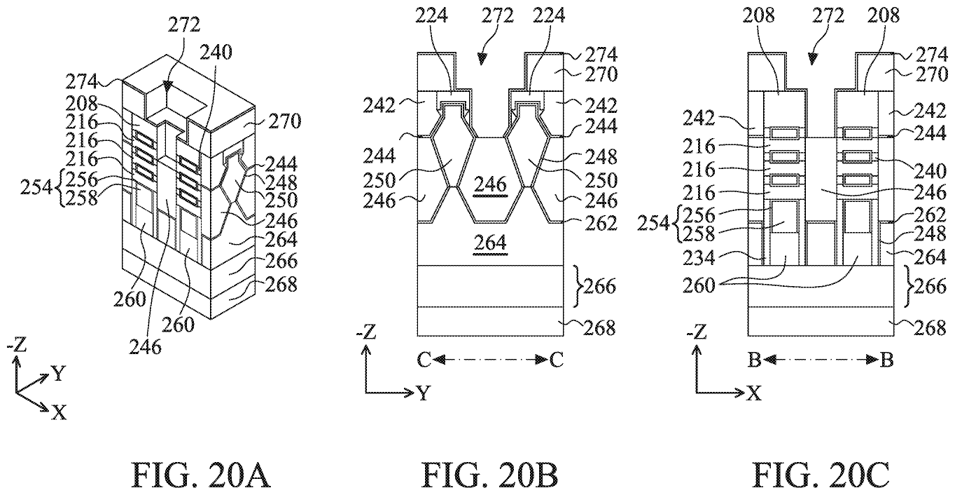

At operation 144, the method 100 (FIG. 1B) forms a spacer layer 274 on sidewalls of the backside trench 272, as shown in FIGS. 20A-20C. The spacer layer 274 may include a dielectric material such as silicon oxide, silicon nitride, silicon carbide, silicon oxynitride, SiCN films, silicon oxycarbide, SiOCN films, and/or combinations thereof. By way of example, the spacer layer 274 may be formed by blanket depositing a dielectric material layer in a conformal manner over the backside of the device 200 using processes such as, a CVD process, an SACVD process, an ALD process, a PVD process, or other suitable process. In the illustrated embodiment, the deposition of the dielectric material layer is followed by an etching-back (e.g., anisotropically) process to remove the dielectric material layer from horizontal surfaces and expose the bottom surface of the S/D feature 246. The dielectric material layer may remain on the sidewalls of the backside trench 272 as the spacer layer 274. In some embodiments, the etching-back process may include a wet etch process, a dry etch process, a multiple-step etch process, and/or a combination thereof. In some embodiments, a thickness of the spacer layer 274 ranges from about 3 nm to about 10 nm. If the thickness of the spacer layer 274 is less than about 3 nm, the spacer layer 274 may be removed during the subsequent cleaning process for forming backside silicide features. If the thickness of the spacer layer 274 is larger than about 10 nm, the spacer layer 274 may become difficult to etch through to expose the S/D features 246.

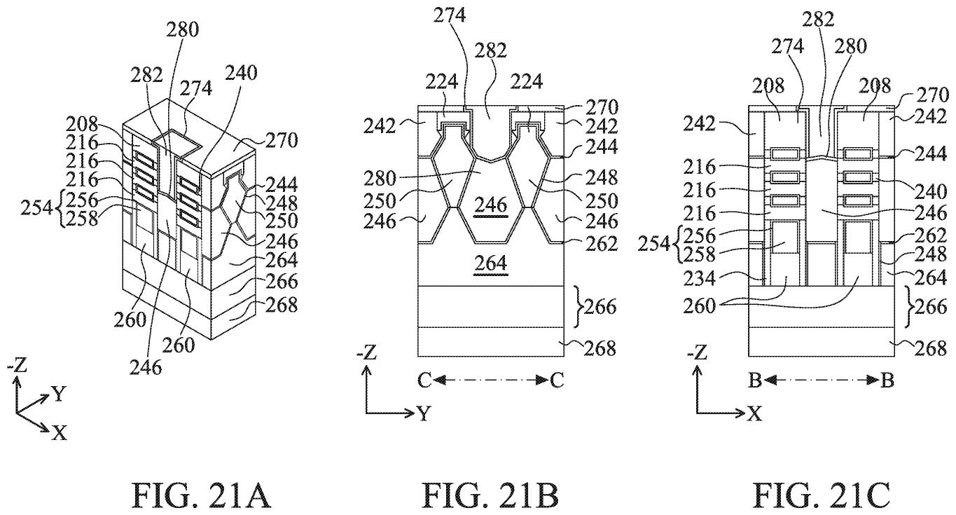

At operation 146, the method 100 (FIG. 1B) forms a backside conductive contact (or backside via) 282 in the backside trench 272 that is formed by removal of the semiconductor layer 242 and the capping layer 244, as shown in FIGS. 21A-21C. The backside conductive contact 282 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. The spacer layer 274 functions as a diffusion barrier layer to prevent the metallic elements in the backside conductive contact 282 diffusing into the semiconductor layer 208 and surrounding dielectric features, such as the STI feature 224 and the ILD layer 250. In one embodiment, the backside conductive contact 282 directly contacts the S/D epitaxial features 246. Alternatively, in an embodiment, the operation 146 optionally forms a silicide feature 280 between the S/D epitaxial features 246 and the backside conductive contact 282 to further reduce contact resistance. In furtherance of the embodiment, the operation 146 first deposits one or more metals into the backside trenches 272, performing an annealing process to the device 200 to cause reaction between the one or more metals and the S/D epitaxial features 246 to produce the silicide feature, and removing un-reacted portions of the one or more metals, leaving the silicide feature in the backside trench 272. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The silicide feature 280 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. A planarization operation, such as a CMP process, is performed to remove excessive conductive material of the backside conductive contact 282 and further thin down the hard mask layer 270. A remaining thickness of the hard mask layer 270 may range from about 3 nm to about 40 nm. As shown in FIG. 21B, the backside conductive contact 282 has a base portion extending above the STI features 224 and a pillar portion between the base portion and the S/D feature 246. The base portion has a larger width than the pillar portion. Since the pillar portion is formed by a self-aligning process, even overlying shift occurs during the forming of the opening 272, it is the base portion that may shift slightly to the left or the right of the pillar portion, while the position of the pillar portion won't change.

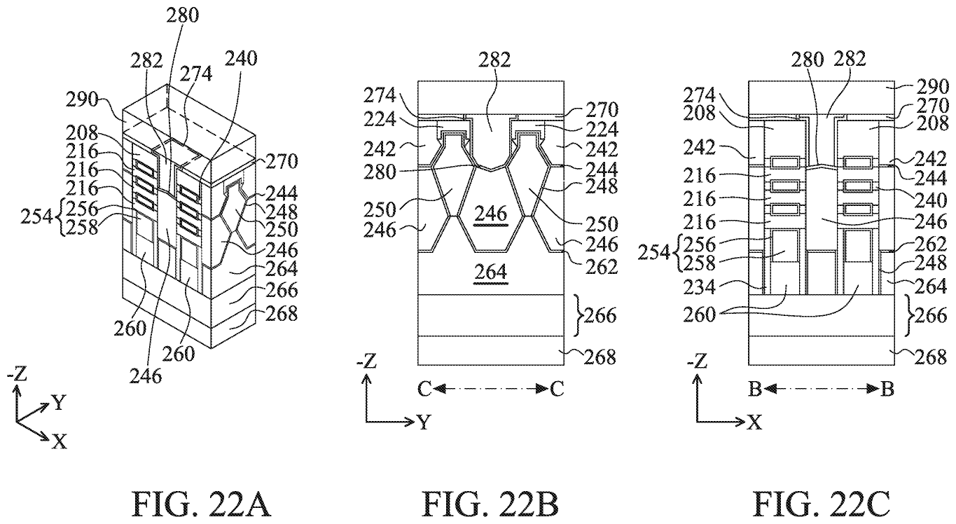

At operation 148, the method 100 (FIG. 1B) forms one or more backside interconnect layers 290 with backside power rails embedded in dielectric layers on the backside of the device 200. The resultant structure is shown in FIGS. 22A-22C according to an embodiment. The backside power rails electrically connect to the backside conductive contact 282. In an embodiment, the backside power rails may be formed using a damascene process, a dual-damascene process, a metal patterning process, or other suitable processes. The backside power rails may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be deposited by CVD, PVD, ALD, plating, or other suitable processes. Although not shown in FIGS. 22A-22C, the backside power rails may include contacts, vias, wires, and/or other conductive features. Having backside power rails beneficially increases the number of metal tracks available in the device 200 for directly connecting to source/drain contacts and vias, including the backside conductive contact 282. The backside power rails may have wider dimension than the first level metal (MO) tracks on the frontside of the device 200, which beneficially reduces the backside power rail resistance.

By forming the sacrificial semiconductor layer 242 before the forming of the S/D features 246, a relatively larger contact area may be reserved between an S/D epitaxial feature and a power rail, effectively further reducing contact resistance and improving device performance. Moreover, a relatively larger contact area provides better overlay control between via and contact structures. In some embodiments, source features among the S/D epitaxial features 246 are connected to the corresponding power lines through the backside power rails, and drain features among the S/D epitaxial features 246 are connected to the corresponding power lines through interconnect structure on the frontside of the device 200.

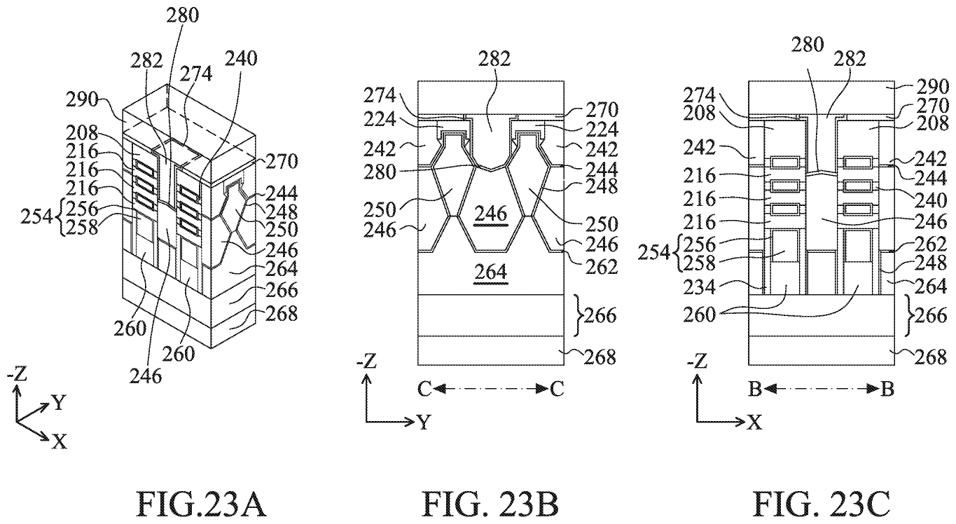

Reference is now made to FIGS. 23A-23C. FIGS. 23A-23C show an alternative embodiment of the resultant structure after the operation 148. Some processes and materials used to form the device 200 may be similar to or the same as what has been described previously in association with FIGS. 1A-22C, and are not repeated herein. One difference is that the bottom surface of the S/D epitaxial feature 246 is recessed during the operation 142 so as to be lower than the adjacent S/D epitaxial features 246. The spacer layer 274 may also extend further downward and have contact with the bottommost channel layer 216 (FIG. 23C).

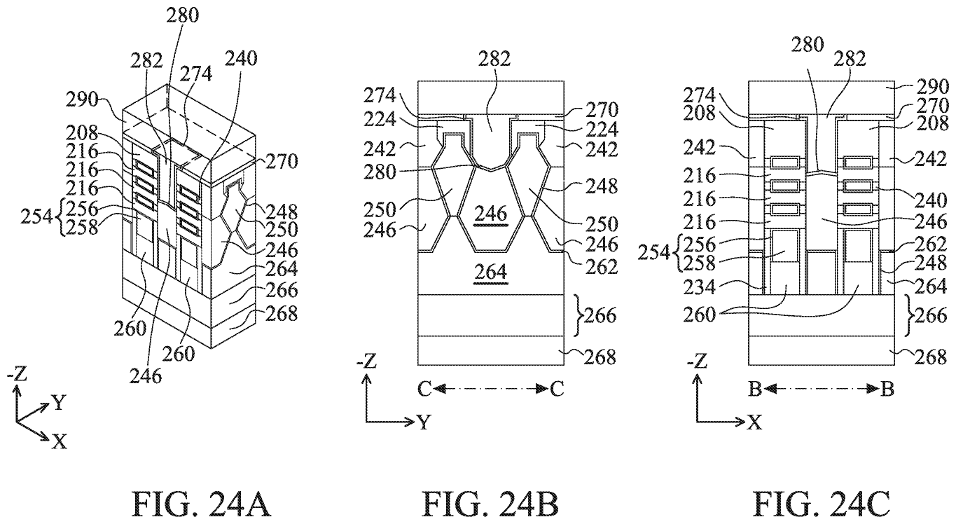

Reference is now made to FIGS. 24A-24C. FIGS. 24A-24C show an alternative embodiment of the resultant structure after the operation 148. Some processes and materials used to form the device 200 may be similar to or the same as what has been described previously in association with FIGS. 1A-22C, and are not repeated herein. One difference is that the formation of the capping layer 244 may be skipped and the semiconductor layer 242 is in contact with the S/D epitaxial feature 246. To selectively remove the semiconductor layer 242 to form the backside trench 272, the material compositions of the semiconductor layer 242 and the S/D epitaxial feature 246 are distinct from each other to exhibit sufficient etching contrast. For example, the semiconductor layer 242 may have a larger concentration of Ge than the S/D epitaxial feature 246 if both comprise SiGe.

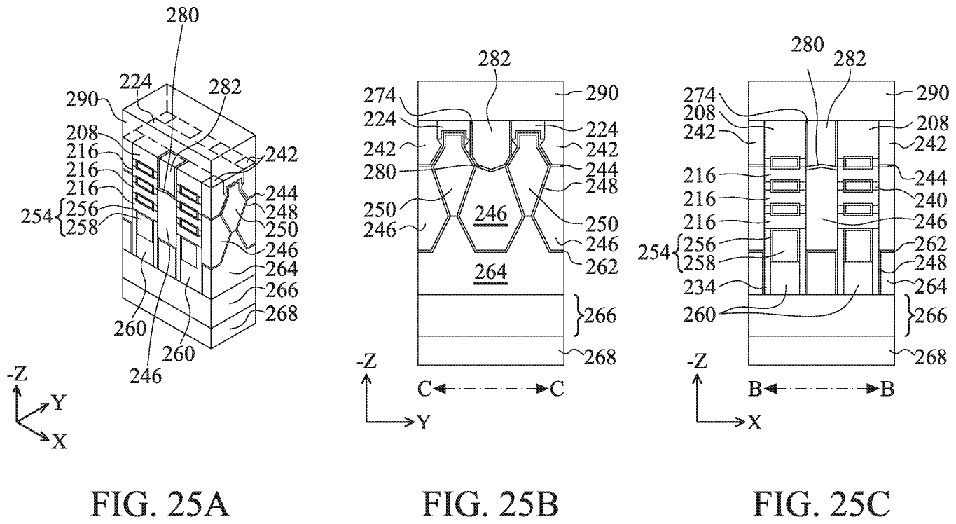

Reference is now made to FIGS. 25A-25C. FIGS. 25A-25C show an alternative embodiment of the resultant structure after the operation 148. Some processes and materials used to form the device 200 may be similar to or the same as what has been described previously in association with FIGS. 1A-22C, and are not repeated herein. One difference is that the hard mask layer 270 is fully removed from the backside of the device 200 during the planarization process. The STI features 224 are exposed after the removal of the hard mask layer 270.

At operation 150, the method 100 (FIG. 1B) performs further fabrication processes to the device 200. For example, it may form one or more interconnect layers on the backside of the device 200, form passivation layers on the backside of the device 200, perform other BEOL processes, and remove the carrier 268.

Although not intended to be limiting, embodiments of the present disclosure provide one or more of the following advantages. For example, embodiments of the present disclosure form a backside contact on a wafer's backside in a self-aligned manner. This advantageously reserves a relatively larger backside contact area to form interconnect structures with relatively lower contact resistance for backside power rails. Further, embodiments of the present disclosure form backside wiring layers, such as backside power rails, to increase the number of metal tracks available in an integrated circuit and increase the gate density for greater device integration. Embodiments of the present disclosure can be readily integrated into existing semiconductor manufacturing processes.

In one exemplary aspect, the present disclosure is directed to a method. The method includes forming a fin over a semiconductor layer, depositing an isolation feature on sidewalls of the fin, recessing a portion of the fin to form a first trench exposing a top surface of the semiconductor layer, forming a sacrificial feature in the first trench, forming an epitaxial feature over the sacrificial feature, exposing a bottom surface of the sacrificial feature, removing the sacrificial feature to form a second trench exposing a bottom surface of the epitaxial feature, and forming a conductive feature in the second trench, the conductive feature electrically coupled to the epitaxial feature. In some embodiment, the method also includes prior to the forming of the epitaxial feature, depositing a capping layer over the sacrificial feature, the epitaxial feature being over the capping layer. In some embodiments, the method also includes after the removing of the sacrificial feature, removing a portion of the capping layer from the second trench. In some embodiments, the capping layer separates the epitaxial feature from contacting the sacrificial feature. In some embodiments, the capping layer covers a top surface of the isolation feature. In some embodiments, the sacrificial feature includes a semiconductor material. In some embodiments, the sacrificial feature includes SiGe. In some embodiments, the method also includes prior to the forming of the conductive feature, depositing a spacer layer on sidewalls of the second trench. In some embodiments, the second trench exposes sidewalls of the isolation feature. In some embodiments, the method also includes forming a hard mask layer on the bottom surface of the sacrificial feature. The hard mask layer includes an opening overlaying the bottom surface of the sacrificial feature, and the removing of the sacrificial feature includes etching the sacrificial feature through the opening.

In another exemplary aspect, the present disclosure is directed to a method. The method includes providing a structure having a frontside and a backside, the structure including a substrate at the backside of the structure and a fin at the frontside of the structure, the fin including a plurality of sacrificial layers and a plurality of channel layers alternately arranged, recessing the fin in a source/drain (S/D) region from the frontside of the structure, thereby exposing a top surface of the substrate, epitaxially growing a semiconductor feature from the top surface of the substrate, forming an S/D epitaxial feature above the semiconductor feature, thinning down the structure from the backside of the structure until the semiconductor feature is exposed, etching the semiconductor feature from the backside of the structure to form a backside trench exposing a bottom surface of the S/D epitaxial feature, depositing a conductive feature in the backside trench, and forming a metal wiring layer on the backside of the structure, the metal wiring layer electrically coupled to the S/D epitaxial feature through the conductive feature. In some embodiments, a top surface of the semiconductor feature is under a bottom surface of a bottommost one of the channel layers. In some embodiments, the method also includes forming inner spacers abutting ends of the sacrificial layers, the semiconductor feature being in physical contact with a bottommost one of the inner spacers. In some embodiments, the method also includes depositing a dielectric layer between the semiconductor feature and the S/D epitaxial feature, and removing the dielectric layer from the backside trench. In some embodiments, an edge portion of the semiconductor feature is not covered by the dielectric layer. In some embodiments, the method also includes removing the sacrificial layers, forming a metal gate structure wrapping around each of the channel layers, and forming a dielectric feature interposing the metal gate structure and the conductive feature. In some embodiments, the method also includes forming an isolation feature disposed on sidewalls of the fin, the semiconductor feature extending upwardly through the isolation feature, and a portion of the semiconductor feature being directly above the isolation feature.

In another exemplary aspect, the present disclosure is directed to a semiconductor structure. The semiconductor structure includes first and second source/drain (S/D) epitaxial features, one or more nanostructures connecting the first and second S/D epitaxial features, a gate structure engaging the one or more nanostructures. The first and second S/D epitaxial features, the one or more nanostructures, and the gate structure are at a frontside of the semiconductor structure. The semiconductor structure also includes a metal wiring layer at a backside of the semiconductor structure, a conductive feature directly under the first S/D epitaxial feature and connecting the metal wiring layer and the first S/D epitaxial feature, and a semiconductor feature directly under the second S/D epitaxial feature. In some embodiments, the semiconductor structure also includes a dielectric layer interposing the semiconductor feature and the second S/D epitaxial feature. In some embodiments, the conductive feature extends to a position directly under the one or more nanostructures.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method, comprising:
forming a fin over a semiconductor layer;
depositing an isolation feature on sidewalls of the fin;
recessing a portion of the fin to form a first trench exposing a top surface of the semiconductor layer;
forming a sacrificial feature in the first trench;
forming an epitaxial feature over the sacrificial feature;
exposing a bottom surface of the sacrificial feature;
removing the sacrificial feature to form a second trench exposing a bottom surface of the epitaxial feature; and
forming a conductive feature in the second trench, wherein the conductive feature electrically couples to the epitaxial feature.

2. The method of claim 1, further comprising:
prior to the forming of the epitaxial feature, depositing a capping layer over the sacrificial feature, wherein the epitaxial feature is over the capping layer.

3. The method of claim 2, further comprising:
after the removing of the sacrificial feature, removing a portion of the capping layer from the second trench.

4. The method of claim 2, wherein the capping layer separates the epitaxial feature from contacting the sacrificial feature.

5. The method of claim 2, wherein the capping layer covers a top surface of the isolation feature.

6. The method of claim 1, wherein the sacrificial feature includes a semiconductor material.

7. The method of claim 6, wherein the sacrificial feature includes SiGe.

8. The method of claim 1, further comprising:
prior to the forming of the conductive feature, depositing a spacer layer on sidewalls of the second trench.

9. The method of claim 1, wherein the second trench exposes sidewalls of the isolation feature.

10. The method of claim 1, further comprising:
forming a hard mask layer on the bottom surface of the sacrificial feature,
wherein the hard mask layer includes an opening overlaying the bottom surface of the sacrificial feature, and the removing of the sacrificial feature includes etching the sacrificial feature through the opening.

11. A method, comprising:
providing a structure having a frontside and a backside, the structure including a substrate at the backside of the structure and a fin at the frontside of the structure, wherein the fin includes a plurality of sacrificial layers and a plurality of channel layers alternately arranged;
recessing the fin in a source/drain (S/D) region from the frontside of the structure, thereby exposing a top surface of the substrate;
epitaxially growing a semiconductor feature from the top surface of the substrate;
forming an S/D epitaxial feature above the semiconductor feature;
thinning down the structure from the backside of the structure until the semiconductor feature is exposed;
etching the semiconductor feature from the backside of the structure to form a backside trench exposing a bottom surface of the S/D epitaxial feature;
depositing a conductive feature in the backside trench; and
forming a metal wiring layer on the backside of the structure, wherein the metal wiring layer electrically couples to the S/D epitaxial feature through the conductive feature.

12. The method of claim 11, wherein a top surface of the semiconductor feature is under a bottom surface of a bottommost one of the channel layers.

13. The method of claim 11, further comprising:
forming inner spacers abutting ends of the sacrificial layers,
wherein the semiconductor feature is in physical contact with a bottommost one of the inner spacers.

14. The method of claim 11, further comprising:
depositing a dielectric layer between the semiconductor feature and the S/D epitaxial feature; and
removing the dielectric layer from the backside trench.

15. The method of claim 14, wherein an edge portion of the semiconductor feature is not covered by the dielectric layer.

16. The method of claim 11, further comprising:
removing the sacrificial layers;
forming a metal gate structure wrapping around each of the channel layers; and
forming a dielectric feature interposing the metal gate structure and the conductive feature.

17. The method of claim 11, further comprising:
forming an isolation feature disposed on sidewalls of the fin,
wherein the semiconductor feature extends upwardly through the isolation feature, and a portion of the semiconductor feature is directly above the isolation feature.

18. A semiconductor structure, comprising:
first and second source/drain (S/D) epitaxial features;
one or more nanostructures connecting the first and second S/D epitaxial features;
a gate structure engaging the one or more nanostructures, wherein the first and second S/D epitaxial features, the one or more nanostructures, and the gate structure are at a frontside of the semiconductor structure;
a metal wiring layer at a backside of the semiconductor structure;
a conductive feature directly under the first S/D epitaxial feature and connecting the metal wiring layer and the first S/D epitaxial feature; and
a semiconductor feature directly under the second S/D epitaxial feature.

19. The semiconductor structure of claim 18, further comprising:
a dielectric layer interposing the semiconductor feature and the second S/D epitaxial feature.

20. The semiconductor structure of claim 18, wherein the conductive feature extends to a position directly under the one or more nanostructures.
